(19) United States
(12) Patent Application Publication
(10) Pub. No.: US 2017/0141332 A1
(43) Pub. Date: May 18, 2017

(54) ORGANIC TRANSISTOR

(71) Applicant: Cambridge Display Technology Limited, Godmanchester (GB)

(72) Inventors: Jeremy Burroughes, Godmanchester (GB); Christopher Newsome, Godmanchester (GB); Daniel Tobjork, Godmanchester (GB)

(73) Assignee: Cambridge Display Technology Limited, Godmanchester (GB)

(21) Appl. No.: 15/322,402

(22) PCT Filed: Jun. 26, 2015
(86) PCT No.: PCT/EP2015/064567

§ 371 Date: Dec. 27, 2016

(30) Foreign Application Priority Data
Jun. 30, 2014 (GB) 1411621.4

(51) Int. Cl. H01L 51/05; H01L 51/10

(52) U.S. Cl. CPC H01L 51/0562; H01L 51/105; H01L 51/0541; H01L 51/0545; H01L 51/0039

(57) ABSTRACT

An organic thin film transistor comprising source and drain electrodes (103, 105); a semiconducting region between the source and drain electrodes; a charge-transporting layer (107) comprising a charge-transporting material extending across the semiconducting region and in electrical contact with the source and drain electrodes; an organic semiconducting layer (109) comprising an organic semiconductor extending across the semiconducting region; a gate electrode (113); and a gate dielectric (111) between the gate electrode and the organic semiconducting layer.

### BACKGROUND OF THE INVENTION

Transistors can be divided into two main types: bipolar junction transistors and field-effect transistors. Both types share a common structure comprising three electrodes with a semiconductive material disposed therebetween in a channel. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semiconductive material which conducts positive charge carriers (holes) or negative charge carriers (electrons) respectively. The semiconductive material may be selected according to its ability to accept, conduct, and donate charge. The ability of the semiconductive material to accept, conduct, and donate holes or electrons can be enhanced by doping the material. The material used for the source and drain electrodes can also be selected according to its ability to accept and inject holes or electrons. For example, a p-type transistor device can be formed by selecting a semiconductive material which is efficient at accepting, conducting, and donating holes, and selecting a material for the source and drain electrodes which is efficient at injecting and accepting holes from the semiconductive material. Good energy-level matching of the Fermi-level in the electrodes with the HOMO (Highest Occupied Molecular Orbital) level of the semiconductive material can enhance hole injection and acceptance. Likewise, an n-type transistor device can be formed by selecting a semiconductive material which is efficient at accepting, conducting, and donating electrons, and selecting a material for the source and drain electrodes which is efficient at injecting electrons into, and accepting electrons from, the semiconductive material. Good energy-level matching of the Fermi-level in the electrodes with the LUMO (Lowest Unoccupied Molecular Orbital) level of the semiconductive material can enhance electron injection and acceptance.

Transistors can be formed by depositing the components in thin films to form thin-film transistors. When an organic material is used as the semiconductive material in such a device, it is known as an organic thin-film transistor (OTFT).

Various arrangements for OTFTs are known. One such device is an insulated gate field-effect transistor which comprises source and drain electrodes with a semiconductive material disposed therebetween in a channel, a gate electrode disposed over the semiconductive material and a layer of insulting material disposed between the gate electrode and the semiconductive material in the channel.

The conductivity of the channel can be altered by the application of a voltage at the gate. In this way the transistor can be switched on and off using an applied gate voltage. The drain current that is achievable for a given voltage is dependent on the mobility of the charge carriers in the organic semiconductor in the active region of the device. Thus, in order to achieve high drain currents with low operational voltages, organic thin-film transistors must have an organic semiconductor which has highly mobile charge carriers in the channel.

High mobility OTFTs containing “small molecule” organic semiconductor materials have been reported, and the high mobility has been attributed, at least in part, to the highly crystalline nature of the small molecule organic semiconductors in the OTFT. Particularly high mobilities have been reported in single crystal OTFTs wherein the organic semiconductor is deposited by thermal evaporation. A single crystal OTFT is disclosed in Podzorov et al, Appl. Phys. Lett. 2003, 83(17), 3504-3506.

Formation of the semiconductor region by solution deposition of a blend of a small molecule organic semiconductor and a polymer is disclosed in Smith et. al., Applied Physics Letters, Vol 93, 253301 (2008); Russell et. al., Applied Physics Letters, Vol 87, 222109 (2005); Ohe et. al., Applied Physics Letters, Vol 93, 053303 (2008); Madec et. al., Journal of Surface Science & Nanotechnology, Vol 7, 455-458 (2009); Kang et. al., J. Am. Chem. Soc., Vol 130, 12273-75 (2008); Chung et al, J. Am. Chem. Soc. (2011), 133(3), 412-415; Lada et al, J. Mater. Chem. (2011), 21(30), 11232-11238; Hamilton et al, Adv. Mater. (2009), 21(10-11), 1166-1171; WO 2005/055248; and WO 2013/041822.

Reducing contact resistance at the source and drain electrodes is disclosed in WO 2009/000683 by selectively forming a self-assembled layer of a dopant for the organic semiconductor on the surface of the source and drain electrodes.

### SUMMARY OF THE INVENTION

In a first aspect the invention provides an organic thin film transistor comprising source and drain electrodes; a semiconducting region between the source and drain electrodes; a charge-transporting layer comprising a charge-transporting material extending across the semiconducting region and in electrical contact with the source and drain electrodes; an organic semiconducting layer comprising an organic semiconductor extending across the semiconducting region; a gate electrode; and a gate dielectric between the gate electrode and the organic semiconducting layer.

In a second aspect the invention provides a method of forming a top-gate, bottom contact organic thin film transistor according to the first aspect, the method comprising the steps of forming the charge-transporting layer on the source and drain electrodes; forming the organic semiconducting layer on the charge-transporting layer; forming the insulating layer over the organic semiconducting layer; and forming the gate electrode over the insulating layer.

In a third aspect the invention provides an organic thin film transistor comprising source and drain electrodes on a surface of a substrate; a semiconducting region between the source and drain electrodes; an organic semiconducting layer extending across the semiconducting region and in electrical contact with the source and drain electrodes; a gate electrode; and an insulating layer between the gate electrode, wherein the source and drain electrodes have a first self-assembled monolayer on a surface thereof and the substrate has a second self-assembled monolayer on part of the substrate surface.

In a fourth aspect the invention provides a method of forming an organic thin film transistor according to the third aspect comprising the steps of: masking an area of the substrate surface defining a boundary of the semiconducting region; forming the first and second self-assembled monolayers; removing the mask; forming the organic semiconducting layer; forming the insulating layer; and forming the gate electrode.

In a fifth aspect the invention provides an organic thin film transistor comprising source and drain electrodes on a surface of a plastic substrate; a semiconducting region between the source and drain electrodes; an organic semiconducting layer extending across the semiconducting region and in electrical contact with the source and drain electrodes; a gate electrode; and an insulating layer between the gate electrode, wherein the substrate has a second self-assembled monolayer on part of the substrate surface.

### DESCRIPTION OF THE FIGURES

The invention will now be described in more detail with reference to the Figures, in which:

FIG. 1A is a schematic illustration of a top-gate transistor according to an embodiment of the invention;

FIG. 1B is a schematic illustration of a bottom-gate transistor according to an embodiment of the invention;

FIG. 2 is a schematic illustration of a process for forming self-assembled monolayers on the substrate and on the source and drain electrodes of a top-gate transistor;

FIG. 3 is a graph of contact resistances and mobilities of devices according to embodiments of the invention containing a charge-transporting polymer layer and a non-polymeric organic semiconductor layer and a comparative device containing a blend of the charge-transporting polymer and non-polymeric organic semiconductor; and

FIG. 4 is a graph of contact resistances and mobilities of devices that have or have not had a source and drain treatment, rinsing of a charge transporting layer and/or doping of a charge-transporting layer;

FIG. 5A is an image of a substrate carrying gold source and drain electrodes treated to form an ODTCS SAM pattern following by inkjet printing of a solvent;

FIG. 5B is an image of a substrate carrying gold source and drain electrodes treated to form an ODTCS SAM pattern and ODT SAM pattern a following by inkjet printing of a solvent;

FIG. 6 is a graph of output characteristics for a device according to an embodiment of the invention; and

FIG. 7 is a graph of transfer characteristics for a device according to an embodiment of the invention.

### DETAILED DESCRIPTION OF THE INVENTION

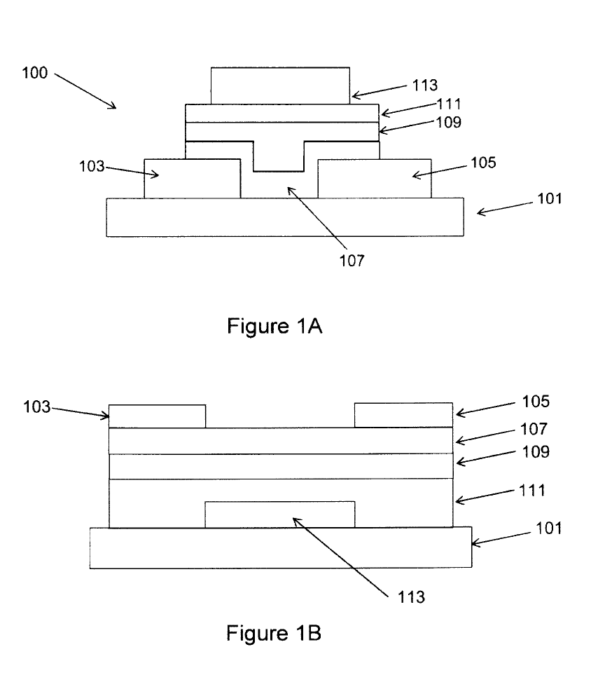

FIG. 1A, which is not drawn to any scale, schematically illustrates a top-gate organic thin-film transistor (OTFT) 100 according to an embodiment of the invention. The illustrated structure may be deposited on a substrate 101 and comprises source and drain electrodes 103, 105. A charge-transporting layer 107 extends between and contacts the source and drain electrodes, and preferably extends over at least part of the upper surface of the source and/or drain electrodes 103, 105. Preferably, the organic semiconducting layer 109, including any part of the organic semiconducting layer extending over the source and drain electrodes, is on the charge-transporting layer 107.

The charge-transporting layer illustrated in FIG. 1A does not have a flat surface due to the different heights of the surfaces of the source and drain electrodes 103, 105 and the surface of the substrate 101 onto which the charge-transporting layer is deposited, although it will be appreciated that the charge transporting layer may provide a smoother surface for deposition of the organic semiconductor as compared to deposition directly across the interface between the source and drain electrodes and the substrate. The charge-transporting layer 107 contains a charge-transporting material which may be doped or undoped. The charge-transporting layer may consist of a single charge-transporting material or may comprise one or more further materials. An organic semiconductor layer 109 is provided on the charge-transporting layer 107. The organic semiconductor layer 109 contains an organic semiconducting material. The organic semiconductor layer 109 may consist of the organic semiconducting material or may contain one or more further materials. Preferably, the charge-transporting layer 107 and the organic semiconductor layer 109 are adjacent. If the charge-transporting layer 107 does not have a flat upper surface, as illustrated in FIG. 1A, then the organic semiconductor layer may have a flat upper surface, as illustrated in FIG. 1A, or may have an upper surface that follows the contours of the charge-transporting layer. The charge-transporting layer 107 and the organic semiconductor layer 109 together form a semiconducting region of the OTFT. It will be appreciated that the channel of the OTFT is within the semiconducting region.

An insulating layer in of dielectric material is deposited over the organic semiconductor layer 109 and may extend over at least a portion of the source and drain electrodes 103, 105. Preferably, the insulating layer 111 is in contact with the organic semiconductor layer 109. Finally, a gate electrode 113 is deposited over the insulating layer 111. The gate electrode 113 is located over the organic semiconductor layer and extends over at least part of the area of the channel. The gate electrode may extend over at least a portion of the source and drain electrodes.

The device of FIG. 1A is a top-gate device. FIG. 1B illustrates a further embodiment in which the OTFT is a bottom-gate device. Like numerals are used as for FIGS. 1A and 1B. In contrast to the top-gate device, the organic semiconductor layer 109 of a bottom gate device is formed before the charge-transporting layer 107, and source and drain electrodes 103, 105 are formed on the charge-transporting layer.

The OTFT as described herein may be a p-type or n-type OTFT.

The charge-transporting layer preferably has a low energy barrier, or no energy barrier to injection of charge from the source electrode into the charge-transporting layer. The charge-transporting layer preferably has a low energy barrier, or no energy barrier to injection of charge from the charge-transporting layer into the organic semiconductor layer.

Optionally, the OTFT is a p-type OTFT and the charge-transporting layer is a hole-transporting layer. The difference between the HOMO of a hole-transporting material of the hole-transporting layer and the work function of the source and drain electrodes is preferably no more than 0.3 eV, more preferably no more than 0.2 eV.

Preferably, the difference between the HOMO of the organic semiconductor material of the organic semiconducting layer and the HOMO of the hole-transporting material is preferably no more than 0.3 eV, more preferably no more than 0.2 eV.

HOMO and work function values as described herein are as measured by an AC2 photoelectron yield spectrometer. LUMO levels as described herein may be measured by cyclic voltammetry.

The hole-transporting material may have a hole mobility of at least 10⁻⁴ cm²/Vs. Field effect mobility may be measured in the saturation regime of OTFTs with a channel width of 2 mm and channel length ranging from 5 to 100 μm.

The charge-transporting layer and the organic semiconductor layer are each preferably formed by depositing a formulation comprising the material or materials to form the layer in question dissolved or dispersed in a solvent or solvent mixture followed by evaporation of the solvent or solvents. The charge-transporting layer is preferably crosslinked to prevent or limit its dissolution during formation of the organic semiconductor layer.

The thickness of the charge-transporting and organic semiconducting layers may independently be controlled. The charge-transporting layer preferably has a thickness in the range of 10-40 nm, optionally 15-30 nm. The organic semiconductor layer preferably has a thickness in the range of 10-40 nm, optionally 15-20 nm. The thickness of charge transporting or organic semiconductor layers formed by solution processing may be controlled by selecting variables including, without limitation, the solvent, concentration and viscosity of the solution, and/or by selecting the deposition conditions for the solution, for example evaporation rate and, in the case of a spin-coated layer, the spin speed, acceleration and spin time.

By depositing separate charge-transporting and organic semiconductor layers, the deposition conditions such as solvent selection and deposition technique may be optimised according to the components of each layer.

The charge-transporting layer may provide an at least partially planarised surface for deposition of the organic semiconducting material.

Organic Semiconductor

The organic semiconductor is preferably a non-polymeric organic semiconductor.

“Non-polymeric” as used herein means a material having a polydispersity of 1, and includes dendrimeric or oligomeric compounds having a polydispersity of 1. Oligomers include, without limitation, a dimer, a trimer, a tetramer or a pentamer. Preferably, non-polymeric organic semiconductors have a molecular weight of less than 5000 Daltons.

Preferably, the organic semiconductor in the organic semiconductor layer is crystalline.

Exemplary non-polymeric organic semiconductors include compounds having a core of at least three fused rings wherein each ring is independently selected from aromatic rings and heteroaromatic rings that are each individually unsubstituted or substituted with one or more substituents. Preferably, the core is substituted with at least one substituent, optionally with one or more solubilising substituents.

Optionally, the non-polymeric organic semiconductor is selected from compounds of formulae (I)-(V):

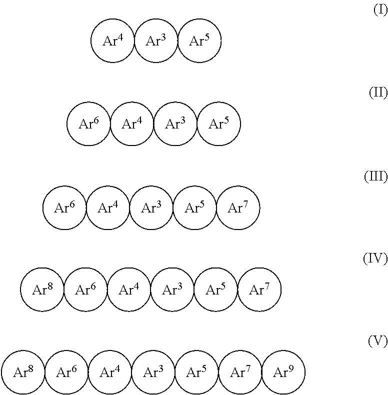

wherein Ar³, Ar⁴, Ar⁵, Ar⁶, Ar⁷, Ar⁸ and Ar⁹ are each independently selected from the group consisting of monocyclic aromatic rings and monocyclic heteroaromatic rings, and at least one of Ar³, Ar⁴, Ar⁵, Ar⁶, Ar⁷, Ar⁸ and Ar⁹ is substituted with at least one substituent X, which in each occurrence may be the same or different and is selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups that may be unsubstituted or substituted with one, two or three alkyl groups having from 1 to 8 carbon atoms, silylethynyl groups that may be unsubstituted or substituted with one, two or three alkyl groups having from 1 to 8 carbon atoms and alkenyl groups having from 2 to 12 carbon atoms and wherein Ar³, Ar⁴ and Ar⁵ may each optionally be fused to one or more further monocyclic aromatic or heteroaromatic rings.

Optionally, at least one of Ar³, Ar⁴, Ar⁵, Ar⁶, Ar⁷, Ar⁸ and Ar⁹ comprises a 5- to 7-membered heteroaryl group containing from 1 to 3 sulfur atoms, oxygen atoms, selenium atoms and/or nitrogen atoms

Optionally, Ar³, Ar⁴, Ar⁵, Ar⁶, Ar⁷, Ar⁸ and Ar⁹ are each independently selected from phenyl and thiophene and wherein at least one of Ar³, Ar⁴, Ar⁵, Ar⁶, Ar⁷, Ar⁸ and Ar⁹ is thiophene.

Optionally, the non-polymeric organic semiconductor has formula (X):

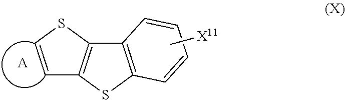

wherein A is a phenyl group or a thiophene group, said phenyl group or thiophene group optionally being fused with a phenyl group or a thiophene group which can optionally be fused with a group selected from a phenyl group, a thiophene group and a benzothiophene group, any of said phenyl, thiophene and benzothiphene groups being unsubstituted or substituted with at least one group of formula X¹¹; and each group X¹¹ may be the same or different and is selected from substituents X as described above, preferably a group of formula CₙH₂ₙ₊₁ wherein n is an integer of from 1 to 20.

Optionally, the core of the non-polymeric organic semiconductor is a hydrocarbyl group formed from at least 3 fused benzene rings.

Optionally, the non-polymeric organic semiconductor is pentancene substituted with one or more tri(C₁₋₁₀ alkyl)silylethynyl substituents.

Solubilising substituents may be substituents that increase solubility of the organic semiconductor in an organic solvent, for example a non-polar organic solvent, as compared to an unsubstituted organic semiconductor.

Exemplary substituents include substituents X described with reference to Formulae (I)-(V), for example one or more alkyl groups, alkoxy groups or silyl groups, including trialkylsilyl and trialkylsilylethynyl.

The non-polymeric organic semiconductor may be an electron-rich compound, for example a compound comprising fused thiophene repeat units.

Exemplary non-polymeric organic semiconductors include compounds of formulae (I)-(V).

The non-polymeric organic semiconductor may be selected from compounds of formulae (VI), (VII), (VIII), (IX) and (X):

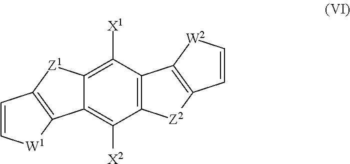

wherein X¹ and X² may be the same or different and are selected from substituents X as described above with reference to formulae (I)-(V); Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

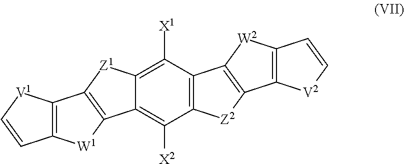

wherein X¹ and X² are as described with reference to formula (VI), Z¹, Z², W¹ and W² are as described with reference to formula (VI) and V¹ and V² are independently S, O, Se or NR⁵ wherein R⁵ is H or a substituent selected from the group consisting of substituted or unsubstituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

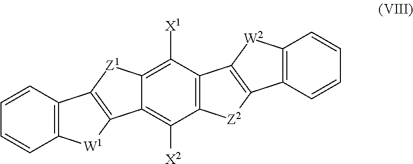

wherein X¹ and X², Z¹, Z², W¹ and W² are as described with reference to formula (VI).

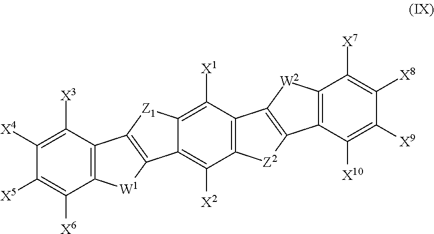

wherein Z¹, Z², W¹ and W² are as described with reference to formula (VI) and X¹-X¹⁰, which may be the same or different, are selected from substituents X as described with reference to formulae (I)-(V);

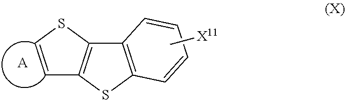

wherein A is a phenyl group or a thiophene group, said phenyl group or thiophene group optionally being fused with a phenyl group or a thiophene group which can optionally be fused with a group selected from a phenyl group, a thiophene group and a benzothiophene group, any of said phenyl, thiophene and benzothiphene groups being unsubstituted or substituted with at least one group of formula X¹¹; and

each group X¹¹ may be the same or different and is selected from substituents X as described with reference to formulae (I)-(V), and preferably is a group of formula CₙH₂ₙ₊₁ wherein n is an integer of from 1 to 20.

In the compound of formula (X), A is optionally selected from:

a thiophene group that is fused with a phenyl group substituted with at least one group of formula X¹¹; or

a phenyl group that may be unsubstituted or substituted with at least one group of formula X¹¹, said phenyl group further optionally being fused with a thiophene group which can be unsubstituted or substituted with at least one group of formula X¹¹ and/or fused with a benzothiophene group, said benzothiphene group being unsubstituted or substituted with at least one group of formula X¹¹, wherein X¹¹ is a group of formula CₙH₂ₙ₊₁ wherein n is an integer of from 1 to 16.

Compounds of formula (X) include the following:

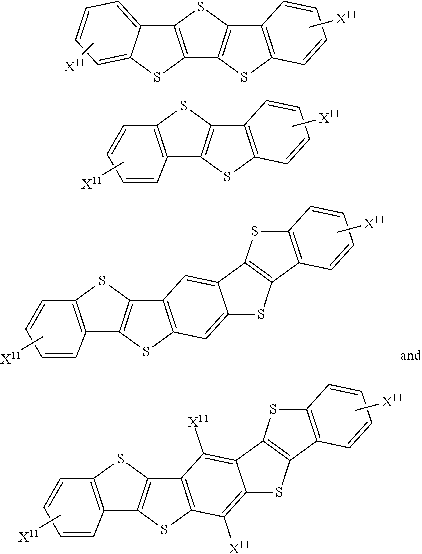

wherein X¹¹ is a group of formula CₙH₂ₙ₊₁ wherein n is an integer of from 1 to 16.

A preferred compound of formula (III) is pentacene substituted with one or more tri(C₁₋₁₀ alkyl)silylethynyl groups. Preferably, a tri(C₁₋₁₀ alkyl)silylethynyl substituent is provided in the 6- and 13-positions of pentacene. An exemplary substituted pentacene is 6,13-(tri-isopropyl-silylethynyl) pentacene (“TIPS pentacene”):

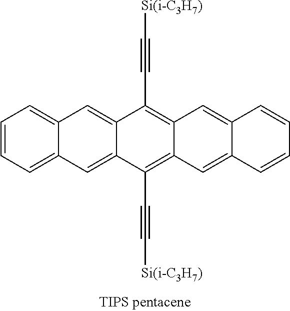

The one or more substituents of the non-polymeric organic semiconductor, for example substituents X and X¹-X¹¹ as described above, may be provided on: (a) one or both of the monocyclic aromatic or heteroaromatic rings at the end(s) of the organic semiconductor core; (b) on one or more of the monocyclic aromatic or heteroaromatic ring or rings that are not at the ends of the organic semiconductor core; or on both of (a) and (b).

Charge-Transporting Material

The charge-transporting material is preferably a semiconducting polymer, more preferably a hole-transporting polymer.

The charge-transporting material is preferably an amorphous material.

A layer of a non-polymeric crystalline organic semiconductor may be more prone to cracking or void formation than a layer of amorphous, preferably polymeric, charge-transporting material, for example due to poor space filling by large crystals. Providing a polymeric charge-transporting layer in contact with the source and drain electrodes may improve charge injection from and to the source and drain electrodes respectively.

Preferred semiconducting polymers are conjugated polymers. Conjugated polymers have a polymer backbone comprising repeat units that are conjugated to one another. Substantially all repeat units in the polymer backbone may be conjugated to adjacent repeat units, or the polymer may contain backbone regions in which conjugation between adjacent repeat units is broken.

Exemplary repeat units of a conjugated polymer include (hetero)arylene repeat units, (hetero)arylenevinylene repeat units and (hetero)arylamine repeat units.

Exemplary (hetero)arylamine repeat units include repeat units of formula (XI):

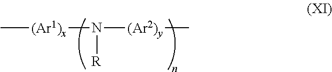

wherein Ar¹ and Ar² in each occurrence are independently selected aryl or heteroaryl groups, each of which may be unsubstituted or substituted with one or more substituents; n is greater than or equal to 1, preferably 1 or 2; R in each occurrence is H or a substituent, preferably a substituent, and x and y are each independently 1, 2 or 3.

Exemplary groups R include alkyl and aryl, for example phenyl.

Any of Ar¹, Ar² and R in the case where R is aryl may independently be substituted with one or more substituents. Preferred substituents are selected from the group R³ consisting of:
alkyl wherein one or more non-adjacent C atoms may be replaced with O, S, substituted N, C═O and —COO— and one or more H atoms of the alkyl group may be replaced with F or aryl or heteroaryl substituted or unsubstituted with one or more groups R⁶,
aryl or heteroaryl substituted or unsubstituted with one or more groups R⁶, NR⁵₂, OR⁵, SR⁵,
fluorine, nitro and cyano; and
crosslinkable groups,

wherein each R⁶ is independently alkyl in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl substituted or unsubstituted with one or more alkyl groups.

Preferably, x, y and n are all 1.

Preferably, Ar¹, Ar² and R are each phenyl and are each independently substituted or unsubstituted with one or more C₁₋₂₀ alkyl groups. In one preferred arrangement, Ar¹ and Ar² are unsubsituted phenyl and R is phenyl substituted with one or more C₁₋₂₀ alkyl groups.

Crosslinkable groups include groups comprising a terminal vinylene group and benzocyclobutene groups.

R may be benzocyclobutene that may be unsubstituted or substituted with one or more substituents R³.

Exemplary repeat units of formula (XI) include the following units, each of which may be unsubstituted or substituted with one or more substituents, optionally one or more C1-20 alkyl groups:

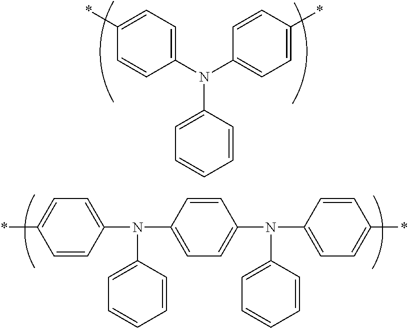

Exemplary arylene repeat units include phenylene, fluorene, and indenofluorene repeat units, each of which may be unsubstituted or substituted with one or more substituents. Exemplary substituents include C₁₋₄₀ hydrocarbyl groups.

Exemplary fluorene repeat units, include repeat units of formula (XII):

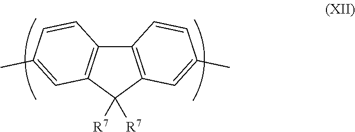

wherein the two groups R⁷, which may be the same or different, are each H or a substituent and wherein the two groups R⁷ may be linked to form a ring.

Each R⁷ is optionally selected from the group consisting of hydrogen; substituted or unsubstituted aryl or heteroaryl, preferably substituted or unsubstituted phenyl; substituted or unsubstituted alkyl wherein one or more non-adjacent C atoms of the alkyl group may be replaced with O, S, substituted N, C═O and —COO—; and crosslinkable groups.

In the case where R⁷ comprises alkyl, optional substituents of the alkyl group include F, cyano, nitro, and aryl or heteroaryl substituted or unsubstituted with one or more groups R⁶ wherein R⁶ is as described above.

In the case where R⁷ comprises aryl or heteroaryl, each aryl or heteroaryl group may independently be substituted. Preferred optional substituents for the aryl or heteroaryl groups include C₁₋₂₀ alkyl.

Optional substituents for the fluorene unit, other than substituents R⁷, are preferably selected from the group consisting of alkyl wherein one or more non-adjacent C atoms may be replaced with O, S, substituted N, C═O and —COO—; substituted or unsubstituted aryl, for example phenyl substituted or unsubstituted with one or more alkyl groups; substituted or unsubstituted heteroaryl; fluorine, cyano and nitro.

Where present, substituted N in repeat units of formula (XII) may independently in each occurrence be NR⁵ as described with reference to formula (XI).

In one preferred arrangement, R⁷ in one or both occurrences is selected from a substituted or unsubstituted C₁-C₂₀ alkyl or a substituted or unsubstituted aryl group, in particular phenyl substituted with one or more C₁₋₂₀ alkyl groups.

In one preferred embodiment, the polymer is a 1:1 copolymer of a repeat unit of formula (XI) and a repeat unit of formula (XII).

The charge-transporting material of the charge-transporting layer may be doped or undoped. The charge-transporting material may be doped before it is deposited to form the charge-transporting layer, or it may be doped after it has been deposited.

An undoped charge-transporting layer may be doped by bringing the undoped layer into contact with one or more dopants, for example by immersion in a dopant solution. Further layers of the OTFT may then be formed on the doped charge-transporting layer.

Exemplary dopants in the case where the charge-transporting material is a hole-transporting material include TCNQ and fluorinated derivatives thereof, preferably F4TCNQ, Mo(tfd)3 and partially fluorinated fullerenes, for example C₆₀F₃₆.

Hole-transporting materials for forming a hole-transporting layer of a p-type OTFT are described herein, wherein the gap between the HOMO level of the hole-transporting material and the HOMO level of the organic semiconducting material is small. It will be appreciated that the device may be a n-type OTFT wherein the charge-transporting layer may be an electron-transporting layer containing an electron transporting material, and wherein a gap between the LUMO level of the electron-transporting material and the LUMO level of the organic semiconducting material is small (e.g. no more than 0.2 eV).

Solvents

Exemplary solvents for dissolution of the non-polymeric organic semiconductor and charge-transporting material include benzene or fused benzenes, each of which may be substituted with one or more substituents. Fused benzenes include compounds having a saturated ring and an unsaturated ring fused to benzene, for example tetralin (1,2,3,4-tetrahydronaphthalene) and indane (2,3-dihydroindene).

The one or more substituents for benzene or fused benzenes may be selected from the group of alkyl, alkoxy and phenoxy substituents, optionally C₁₋₁₀ alkyl and C₁₋₁₀ alkoxy substituents. Exemplary solvents include xylenes; trimethylbenzenes; ethylbenzene; n-butylbenzene; n-heptylbenzene; anisole substituted with one or more C₁₋₅ alkyl groups, for example methylanisole; methylnaphthalene; phenoxytoluene; and methoxynaphthalene.

The solvent may have a boiling point in the range of 60-240° C., and may have a boiling point of at least 100° C.

The choice of solvent for a crystalline organic semiconductor may affect crystal formation. Preferred solvents for non-polymeric crystalline organic semiconductors, in particular compounds of formula (X), are C₁₋₁₀ alkylbenzenes, The solvent for a crystalline organic semiconductor preferably has a boiling point of at least 120° C.

Solution Processing

Suitable methods for forming the charge-transporting layer and the organic semiconducting layer include coating methods, in which an entire surface is coated indiscriminately, and printing processes wherein the composition is selectively deposited on some but not all of a surface.

Exemplary coating processes include spin coating, dip-coating, slot die coating and doctor blade coating.

Exemplary printing processes include inkjet printing, flexographic printing and gravure printing.

Following deposition, the solvent may be allowed to evaporate in ambient conditions. Alternatively, the solvent may be evaporated at elevated temperature, for example at least 50° C., and/or at reduced pressure.

Source, Drain and Gate Electrodes

The source, drain and gate electrodes can be selected from a wide range of conducting materials for example a metal (e.g. gold), metal alloy, metal compound (e.g. indium tin oxide) or conductive polymer.

Thicknesses of the gate electrode, source and drain electrodes may be in the region of 5-200 nm as measured by Atomic Force Microscopy (AFM).

The surface of the source and drain electrodes may be treated to alter the work function and/or wettability of these electrodes, as described in more detail below. Work functions of source and drain electrodes referred to herein are the work functions of the untreated material unless a treatment has been applied in which case the work function is as measured at the surface of the electrodes following treatment.

Gate Insulating Layer

The gate insulating layer comprises a dielectric material selected from insulating materials having a high resistivity. The dielectric constant, k, of the gate dielectric is typically around 2-3 although materials with a high value of k are desirable because the capacitance that is achievable for an OTFT is directly proportional to k, and the drain current is directly proportional to the capacitance. Thus, in order to achieve high drain currents with low operational voltages, OTFTs with thin dielectric layers are preferred. The thickness of the insulating layer is preferably less than 2 micrometres, more preferably less than 500 nm.

The gate dielectric material may be organic or inorganic. Preferred inorganic materials include SiO₂, SiₓN_{y}, silicon oxynitride and spin-on-glass (SOG). Organic dielectric materials include fluorinated polymers such as polytetrafluoroethylene (PTFE), perfluoro cyclo oxyaliphatic polymer (CYTOP), perfluoroalkoxy polymer resin (PFA), fluorinated ethylene-propylene (FEP), polyethylenetetrafluoroethylene (ETFE), polyvinylfluoride (PVF), polyethylenechlorotrifluoroethylene (ECTFE), polyvinylidene fluoride (PVDF), polychlorotrifluoroethylene (PCTFE), perfluoro elastomers (FFKM) such as Kalrez (RTM) or Tecnoflon (RTM), fluoro elastomers such as Viton (RTM), Perfluoropolyether (PFPE) and a polymer of tetrafluoroethylene, hexafluoropropylene and vinylidene fluoride (THV).

Non-fluorinated organic polymer insulator materials may also be used and include polymers such as poly vinylalcohol (PVA), polyvinylpyrrolidone, polyvinylphenol, acrylates such as polymethylmethacrylate (PMMA) and benzocyclobutanes (BCBs) available from Dow Corning. The insulating layer may be formed from a blend of materials. A multi-layered structure may be used in place of a single insulating layer.

The gate dielectric material may be deposited by thermal evaporation under vacuum or by lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor layer, it should not result in dissolution of the organic semiconductor layer. Likewise, the dielectric material should not be dissolved if the organic semiconductor layer is deposited onto it from solution. Techniques to avoid such dissolution include: use of orthogonal solvents, that is use of a solvent for deposition of the uppermost layer that does not dissolve the underlying layer; and crosslinking of the underlying layer.

Wettability Modification and Wettability Patterning

The substrate surface between the source and drain electrodes, and/or the surface of the source and drain electrodes, may be treated to alter wettability of the substrate and or electrode surface. Self-assembled monolayers (SAMs) may be formed to alter surface wettability.

Optionally, wettability is modified using a self-assembling material of formula (XIII):

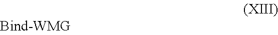

wherein Bind represents a binding group; and WMG is a wetting modification group. Exemplary groups Bind include thiol (in particular for binding to gold source and drain electrodes) and silane, for example trimethylsilyl, or silazane groups (particularly preferred for binding to a glass substrate).

WMGs may increase or decrease wettability of the substrate prior to SAM formation.

Exemplary WMGs include C₁₋₂₀ alkyl, phenyl, C₁₋₂₀ alkyl-phenyl, partially fluorinated C₁₋₂₀ alkyl and C₁₋₂₀ perfluoroalkyl.

Fluorinated WMGs are particularly suitable for reducing wettability.

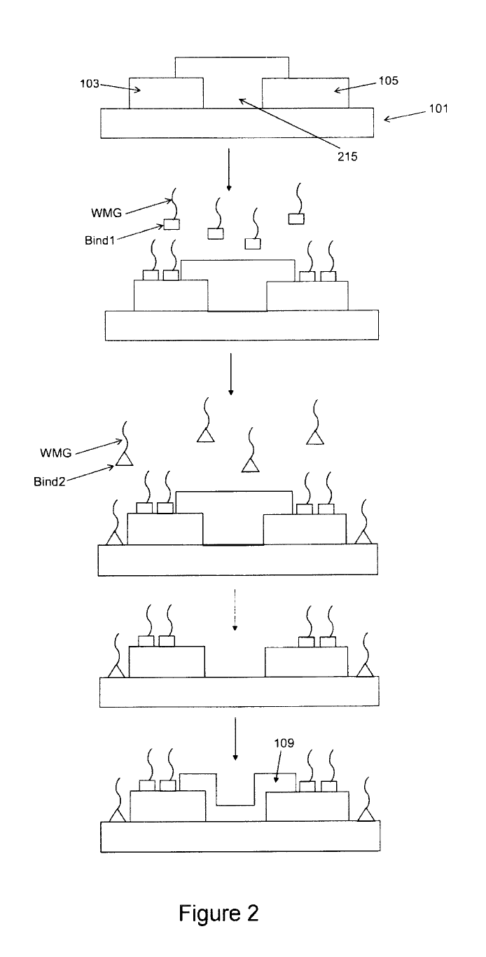

With reference to FIG. 2, the surface of a substrate carrying source and drain electrodes 103, 105 is masked between the source and drain electrodes by a mask 215. Preferably, the mask extends over part of the surface of the source and drain electrodes. The mask may be a photoresist patterned by photolithography.

A first monolayer-forming material comprising binding group Bind1 that binds to the source and drain electrodes and a WMG is applied to selectively form a monolayer on the source and drain electrodes that reduces wettability of the source and drain electrodes by the formulation to be deposited on the substrate. Exemplary materials for forming a monolayer that selectively binds to gold source and drain electrodes include alkanethiols and partially fluorinated and perfluorinated alkylthiols, for example octadecanethiol (ODT) and perfluorodecanethiol (PFDT).

A second monolayer-forming material comprising binding group Bind2 that binds to the substrate and a WMG is applied to selectively form a monolayer on the substrate outside the semiconducting region that reduces wettability of the source and drain electrodes by the formulation to be deposited on the substrate. The mask prevents formation of the monolayer in the semiconducting region. Exemplary materials for forming a monolayer that selectively binds to glass include silanes and silazanes, for example hexamethyldisilazane (HMDS), octadecyltrichlorosilane (ODTCS) and perfluorodecyl trichlorosilane (PFDTCS).

The WMG of the first and second monolayer-forming materials may be the same or different. In a preferred embodiment they are the same.

The mask is then removed and the formulation containing the material or materials to form the layer in contact with the substrate and the source and drain electrodes is deposited. This layer may be a charge-transporting layer or, according to this embodiment, the charge transporting layer may be omitted in which case the layer is the organic semiconducting layer 109. The semiconducting region is more wettable than the substrate surface outside the semiconducting region.

Formation of a SAM in the semiconducting region from unreacted monolayer-forming material during or after removal of the mask may be avoided by rinsing the substrate following SAM formation and/or using a dilute formulation containing the monolayer-forming material.

FIG. 2 illustrates an embodiment in which first and second monolayer-forming materials are applied separately. In another embodiment, the first and second monolayer-forming materials may be applied simultaneously. If first and second monolayers are applied separately then they may be applied in any order.

Each of the first and second monolayer-forming materials may be deposited from a solution in a solvent or solvent mixture. The solution may be printed or coated onto the surface to be treated, or the surface to be treated may be immersed in the solution. The solvent or solvent mixture should be a solvent that does not dissolve the mask 215.

As an alternative to use of non-wetting monolayers at least part of the substrate surface outside the area between the source and drain electrodes and part of the surface of the source and drain electrodes outside the desired wetting area may be masked using a non-wetting material, for example by a non-wetting photoresist, followed by deposition of the organic semiconductor on the exposed, higher wettability areas.

Work Function Modification

The effective work function of the source and drain electrodes may be altered by treatment with a dopant, preferably an organic dopant, or by treatment with a SAM. Exemplary dopants include charge-neutral dopants, for example Mo(tfd)3 and substituted or unsubstituted tetracyanoquinodimethane (TCNQ). An exemplary substituted TCNQ is tetrafluorotetracyanoquinodimethane (F4TCNQ).

A SAM for modifying the workfunction of source and drain electrodes may comprise a binding group as described with reference to Formula (XIII) and a work function modifying group, for example a fluorinated benzene. An exemplary SAM for work function modification is pentafluorobenzenethiol.

If the surface of the source and drain electrodes is at least partially covered with a material that modifies the wettability or work function of the electrodes then it will be appreciated that the charge-transporting layer and/or organic semiconductor layer may not directly contact the material of the source and drain electrodes, but will be in electrical contact with the source and drain electrodes.

The source and drain electrode surfaces may be treated with an oxygen plasma before any dopant or SAM is applied to the electrode surfaces.

In a further embodiment WMG increases wettability of the substrate surface. This may be particularly advantageous for low wettability plastic substrates. In this embodiment, mask 215 is provided on the substrate to expose regions in which the SAM is to be applied. The self-assembling material is applied and the mask is removed as described with reference to FIG. 2 to form a SAM on the substrate surface wherein regions in which the SAM has been applied have higher wettability than masked regions of the substrate.

### EXAMPLES

### Example 1

Source and drain electrodes were formed on a glass substrate by evaporating a 5 nm layer of chrome on a glass substrate followed by an overlying 40 nm layer of gold, and patterning of the chrome and gold layers to define source and drain electrodes with a channel width of 5 or 10 nm.

The substrate carrying the source and drain electrodes was exposed to an oxygen plasma and then immersed in a dopant solution comprising 0.25 mg Mo(tfd)3 per 1 ml o-xylene for a period of 5 minutes.

A charge-transporting layer of Polymer 1, described in WO 99/54385, extending over and between the source and drain electrodes was formed by spin-coating a solution of the polymer in 4-methylanisole followed by evaporation of the solvent and crosslinking the polymer by heating at 180° C. for 30 minutes on a hotplate in a dry nitrogen environment. The polymer film was rinsed to remove any uncrosslinked polymer.

In an optional step, the polymer film was doped by immersion in a Mo(tfd)3 solution (0.25 mg per 1 ml xylene) for a period of 5 minutes.

A ca. 6 nm layer of Organic Semiconductor 1 was formed on the charge-transporting layer by spin-coating from a 0.35% w/v o-xylene solution.

A 300 nm dielectric layer of a fluorinated material was formed on the organic semiconductor layer, and a gate electrode was formed on the dielectric layer by evaporating a 3 nm layer of chrome and a 300 nm layer of aluminium.

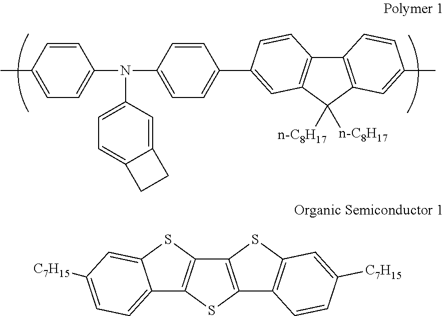

The work function of the Au electrode prior to treatment with Mo(tfd)3 was 40.8-5.0 eV and 5.4 eV after treatment, as measured by AC2 photoelectron yield spectrometry.

Polymer 1 has a HOMO of 50.4-5.5 eV as measured by AC2 photoelectron yield spectrometry.

Organic Semiconductor 1 has a HOMO of 5.3-5.4 eV as measured by AC2 photoelectron yield spectrometry.

It will be appreciated that the HOMO of Polymer 1 provides little or no barrier to hole transport from Polymer 1 to Organic Semiconductor 1.

Devices having polymer thicknesses of 2.6, 4.6, 14, 24 and 33 nm in which the polymer was doped before formation of the organic semiconductor layer were made. Devices having polymer thicknesses of 2.6, 4.6 and 14 nm in which the polymer was not doped before formation of the organic semiconductor layer were also made.

For the purpose of comparison, a device was formed in which the layers of Polymer 1 and Organic Semiconductor 1 were replaced with a single 37 nm thick layer of a blend of Polymer 1 (65 wt %) and Organic Semiconductor 1 (35 wt %).

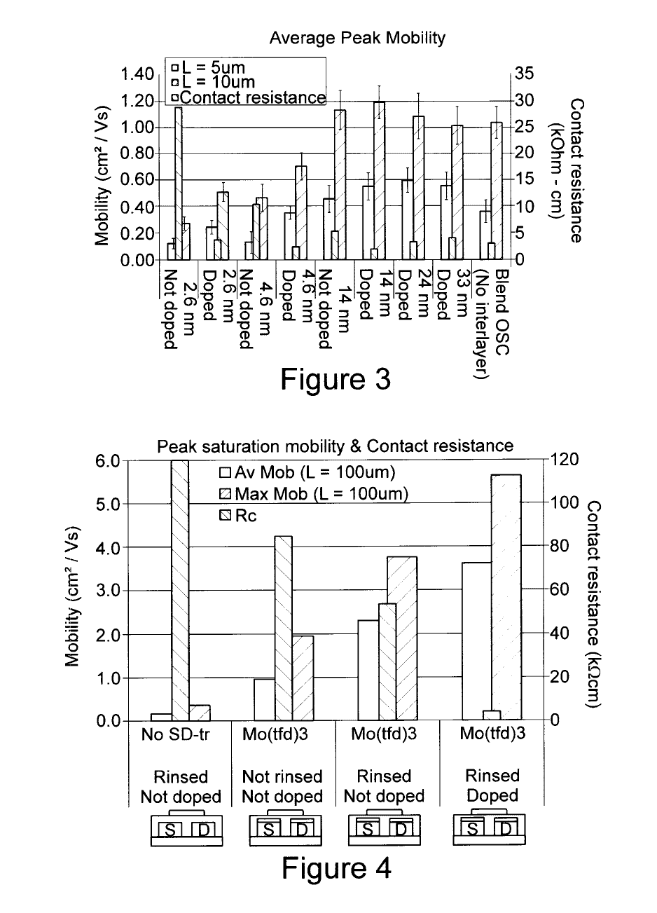

With reference to FIG. 3, doping of the charge-transporting layer before formation of the organic semiconductor layer causes a several-fold reduction in contact resistance.

The on/off ratio of the devices having a doped charge-transporting layer with a thickness of 14-33 nm was 10³-10⁴.

The on/off ratio of the device having a doped charge-transporting layer with a thickness of 14 nm was 10⁷.

Although there is a reduction in the on/off ratio upon doping of the charge-transporting layer, the ratio for the doped devices is comparable to that of the device containing the single layer of a blend of Polymer 1 and Organic Semiconductor 1, for which the on/off ratio was 103.

Optimum mobility is at a polymer thicknesses between 14 and 33 nm.

### Example 2

Gold source and drain electrodes carried on a glass substrate were treated with oxygen plasma. The substrate carrying the source and drain electrodes was then immersed in a dopant solution comprising 0.25 mg Mo(tfd)3 per 1 ml o-xylene for a period of 5 minutes. A layer of Polymer 1 illustrated above was formed to a thickness of 5-40 nm by spin-coating from a 0.5-1 w/v % 4-methylanisole solution, with a lower concentration being used for lower thickness. The polymer layer was cross-linked by heating on a hot plate at 180° C. for 30 minutes in an inert atmosphere. The polymer layer was rinsed in xylene to remove any uncrosslinked polymer.

The polymer film was doped by immersion in a toluene or o-xylene solution of Mo(tfd)3, spin-rinsed with o-xylene to remove excess Mo(tfd)3, and then heated on a hotplate at 60° C. for 10 minutes.

The organic semiconductor layer was formed by inkjet printing a 1 w/v % solution of dioctylbenzothienobenzothiophene (C8BTBT) from 1,2,4-trimethylbenzene solution on the polymer layer surface across the TFT-channel region.

A 300 nm dielectric layer of a fluorinated material was formed on the organic semiconductor layer, and a gate electrode was formed on the dielectric layer by evaporating a 3 nm layer of chrome and a 300 nm layer of aluminium.

For the purpose of comparison, a device without source and drain treatment and no hole-transporting layer was prepared, and a device with source and drain treatment but no hole-transporting layer was prepared.

Results are provided in Table 1.

TABLE 1

| | | | SD | SD |
|---|---|---|---|---|
| | No SD | SD | treatment, | treatment, |
| | treatment, | treatment, | spin-coated | inkjet printed |
| | no hole- | no hole- | hole- | hole- |
| Device | transporting | transporting | transporting | transporting |
| Treatment | layer | layer | layer | layer |
| Average | <0.1 | 0.4 | >3 | 2.5 |
| mobility | | | | |
| (cm²/Vs) | | | | |
| Maximum | <0.1 | 0.7 | >5 | 4.7 |
| mobility | | | | |
| (cm²/Vs) | | | | |
| Contact | >300 | >50 | ~4.5 | ~4.7 |
| resistance | | | | |
| (kΩcm | | | | |
| at −40 | | | | |
| V Vg) | | | | |

It can be seen that treatment of the source and drain electrodes alone gives an improvement in mobility and contact resistance, but the further improvement upon inclusion of a hole-transporting layer is very marked.

With reference to FIG. 4, advantages of both source and drain treatment, rinsing the polymer layer and doping of the polymer layer of the devices of Example 2 are apparent.

Devices having 100 micron channel length and 2 mm channel width and polymer layer thicknesses of 3, 5 and 14 nm thicknesses were prepared by the method of this Example 2. The effect of the polymer layer thickness is set out in Table 2.

TABLE 2

| | Average | Maximum | Contact |
|---|---|---|---|
| Polymer layer | mobility | mobility | resistance (kΩcm |
| thickness(nm) | (cm²/Vs) | (cm²/Vs) | at −40 V Vg) |
| 3 | 1.5 | 3.2 | 14 |
| 5 | 1.8 | 4.5 | 12 |
| 14 | 3.5 | 5.1 | 5 |

Contact resistance was extracted by using the transmission line method (TLM) from devices having a channel length of 5, 10, 20, 30, 50 & 100 μm at a gate voltage of −40V.

As shown in Table 2, contact resistance decreases and mobility increases with increasing polymer layer thicknesses. The present inventors have found that the hole-transporting layer preferably has a thickness of up to 30 nm.

### Example 3

Devices having a channel length of 10 microns or 100 microns were prepared as described in Example 2, except that the organic semiconductor layer was formed by spin coating a 1 w/v % solution of dioctylbenzothienobenzothiophene (C8BTBT) from 0-xylene solution on the polymer layer surface across the TFT-channel region. For the purpose of comparison, a device was prepared without the polymer layer.

TABLE 3

| Device | No polymer layer | Polymer layer |
|---|---|---|
| On/off ratio | ~200 | 10⁵-10⁷ |
| Contact resistance (kOhm | >10 | <2 |
| cm) | | |
| Mobility (cm²/Vs) at 10 | 0.1 | >3 |
| micron channel length | | |
| Mobility (cm²/Vs) at 100 | <3 | >4 |
| micron channel length | | |

As shown in Table 3, the presence of the polymer layer results in a substantial reduction in contact resistance and substantial increases in both mobility and on/off ratio.

### Example 4

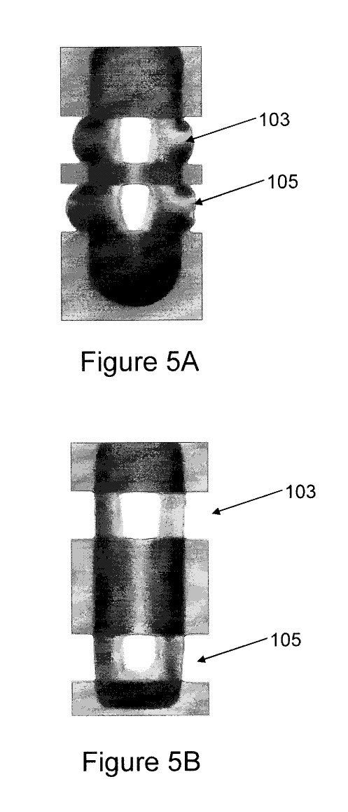

A substrate carrying gold source and drain electrodes lines having a width of 100 nm was treated with ODTCS only to form a SAM of ODTCS outside a 200 nm wide wetting area followed by inkjet printing of benzylalcohol onto the wetting area. With reference to FIG. 5A, the benzylalcohol is confined to the wetting area defined by the ODTCS. The surface of the gold source and drain electrodes is wetted due to the relatively poor binding of ODTCS on gold.

FIG. 5B illustrates a substrate carrying source and drain electrodes that has been treated with both ODTCS and ODT. The ODT treatment prevents wetting on the source and drain electrodes.

### Example 5

An OTFT having a channel length of 100 microns and channel width of 2 mm was formed by treating a substrate carrying gold source and drain electrodes to form SAM patterns of PFDT & PFDTCS followed by inkjet printing a 0.25 wt % solution of Polymer 1, described above, from a 1:1 v/v mixture of 1,24-trimethylbenzene and 4-methylanisole followed by crosslinking of the polymer to form a charge-transporting layer followed by inkjet printing a 1 wt % solution of C8BTBT, described above, in 1,24-trimethylbenzene to form an organic semiconductor layer.

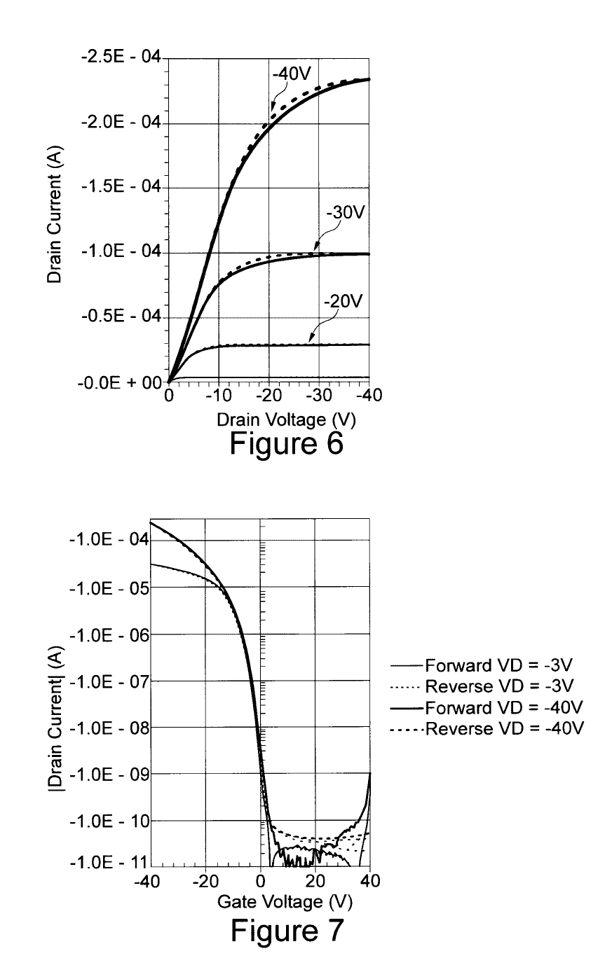

FIG. 6 is a graph of output characteristics and FIG. 7 is a graph of transfer characteristics in which solid lines represent forward Vg and dotted lines represent reverse Vg.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic thin film transistor comprising source and drain electrodes; a semiconducting region between the source and drain electrodes; a charge-transporting material layer comprising a charge-transporting polymer extending across the semiconducting region and in electrical contact with the source and drain electrodes; an organic semiconducting layer comprising an organic semiconductor extending across the semiconducting region; a gate electrode; and a gate dielectric between the gate electrode and the organic semiconducting layer.

2. The organic thin film transistor according to claim 1 wherein the charge-transporting polymer is a hole-transporting polymer.

3. The organic thin film transistor according to claim 2 wherein a difference between the work function of the source and drain electrodes and a HOMO level of the hole-transporting polymer is no more than 0.3 eV.

4. The organic thin film transistor according to claim 2 wherein a difference between a HOMO level of the hole-transporting polymer and a HOMO level of the organic semiconducting material is no more than 0.3 eV.

5. The organic thin film transistor according to claim 1 wherein the charge-transporting polymer is doped.

6. The organic thin film transistor according to claim 1 wherein the charge-transporting layer is crosslinked.

7. The organic thin film transistor according to claim 1 wherein the charge-transporting polymer comprises repeat units of formula (XI): 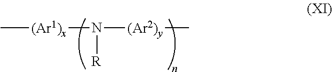
wherein Ar¹ and Ar² in each occurrence are independently selected from substituted or unsubstituted aryl or heteroaryl groups, n is greater than or equal to 1, R in each occurrence is H or a substituent, and x and y are each independently 1, 2 or 3.

8. The organic thin film transistor according to claim 1 wherein the organic semiconductor is a non-polymeric organic semiconductor.

9. The organic thin film transistor according to claim 8 wherein the non-polymeric organic semiconductor is selected from compounds of formulae (I)-(V): 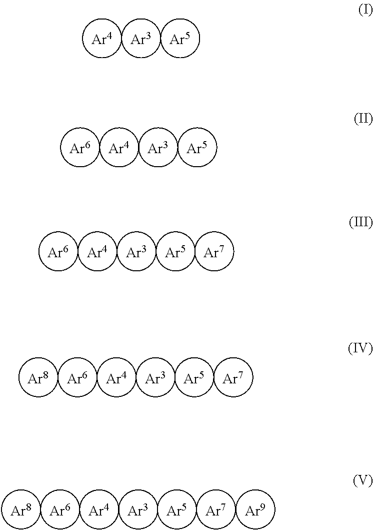
wherein Ar³, Ar⁴, Ar⁵, Ar⁶, Ar⁷, Ar⁸ and Ar⁹ are each independently selected from the group consisting of monocyclic aromatic rings and monocyclic heteroaromatic rings, and at least one of Ar³, Ar⁴, Ar⁵, Ar⁶, Ar⁷, Ar⁸ and Ar⁹ is substituted with at least one substituent X, which in each occurrence may be the same or different and is selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups that may be unsubstituted or substituted with one, two or three alkyl groups having from 1 to 8 carbon atoms, silylethynyl groups that may be unsubstituted or substituted with one, two or three alkyl groups having from 1 to 8 carbon atoms and alkenyl groups having from 2 to 12 carbon atoms and wherein Ar³, Ar⁴ and Ar⁵ may each optionally be fused to one or more further monocyclic aromatic or heteroaromatic rings.

10. The organic thin film transistor according to claim 1 wherein a dopant is provided on a surface of the source and drain electrodes.

11. A method of forming a top-gate, bottom contact organic thin film transistor, the method comprising the steps of forming the charge-transporting layer on the source and drain electrodes; forming the organic semiconducting layer on the charge-transporting layer; forming the insulating layer over the organic semiconducting layer; and forming the gate electrode over the insulating layer.

12. The method according to claim 11 wherein the charge-transporting layer is crosslinked prior to the formation of the organic semiconducting layer.

13. The method according to claim 11 wherein the charge-transporting layer is doped prior to the formation of the organic semiconducting layer.

14-17. (canceled)

18. An organic thin film transistor comprising source and drain electrodes on a surface of a plastic substrate; a semiconducting region between the source and drain electrodes; an organic semiconducting layer extending across the semiconducting region and in electrical contact with the source and drain electrodes; a gate electrode; and an insulating layer between the gate electrode, wherein the substrate has a second self-assembled monolayer on part of the substrate surface.

19. The organic thin film transistor according to claim 18 wherein the self-assembled monolayer is formed on the area of the substrate surface defining a boundary of the semiconducting region.
